(19) United States
(12) Patent Application Publication
(10) Pub. No.: US 2014/0354325 A1
(43) Pub. Date: Dec. 4, 2014

(54) SEMICONDUCTOR LAYOUT STRUCTURE AND TESTING METHOD THEREOF

(71) Applicant: UNITED MICROELECTRONICS CORP., HSINCHU (TW)

(72) Inventors: Chun-Ming Chang, Kaohsiung City (TW); Chun-Liang Hou, Hsinchu County (TW); Wen-Jung Liao, Hsinchu City (TW)

(73) Assignee: UNITED MICROELECTRONICS CORP., HSINCHU (TW)

(21) Appl. No.: 13/903,102

(22) Filed: May 28, 2013

(51) Int. Cl. G01R 31/26

(52) U.S. Cl. CPC G01R 31/2621
USPC 324/762.09

(57) ABSTRACT

A semiconductor layout structure and a testing method thereof are disclosed. The semiconductor layout structure includes a device under test (DUT), a first testing pad, a second testing pad and a plurality of third testing pads. The DUT includes a plurality of metal-oxide-semiconductor (MOS) transistors. Each of the MOS transistors includes a first terminal, a second terminal and a third terminal. The first testing pad is coupled to the first terminals for being applied a first voltage. The second testing pad is coupled to the second terminals for being applied a second voltage. The third testing pads are respectively coupled to the third testing pads for being applied a third voltage. The third testing pads are electrical insulated from each other. The third voltage is larger than the first voltage and the second voltage.

### BACKGROUND OF THE INVENTION

1. Field of the Invention

The invention relates in general to the invention is related to a semiconductor layout structure and a testing method thereof, and more particularly to a semiconductor layout structure including a plurality of metal-oxide-semiconductor (MOS) transistors, and a testing method thereof for testing the MOS transistors.

2. Description of the Related Art

During semiconductor manufacturing process, the performance of a dielectric film should be evaluated by a wafer acceptance test (WAT) after the manufacturing process, in order to confirm the life time of the semiconductor element.

The accuracy of the wafer acceptance test will affect the quality of the semiconductor element. For example, if an error bar of the wafer acceptance test is large, the life time of the semiconductor element cannot be precisely forecasted.

### SUMMARY OF THE INVENTION

The invention is directed to a semiconductor layout structure and a testing method thereof. A plurality of metal-oxide-semiconductor (MOS) transistors are arranged for testing. The semiconductor layout structure and the testing method thereof do not need any extra wafer acceptance test (WAT) tool. Further, the number of the MOS transistors can be easily increased to reduce the error bar due to the high sample size. Moreover, even if the number of the MOS transistors is large, the testing time is still less and the testing area is still small.

According to a first aspect of the present invention, a semiconductor layout structure is disclosed. The semiconductor layout structure includes a device under test (DUT), a first testing pad, a second testing pad and a plurality of third testing pads. The DUT includes a plurality of metal-oxide-semiconductor (MOS) transistors. Each of the MOS transistors includes a first terminal, a second terminal and a third terminal. The first testing pad is coupled to the first terminals for being applied a first voltage. The second testing pad is coupled to the second terminals for being applied a second voltage. The third testing pads are respectively coupled to the third testing pads for being applied a third voltage. The third testing pads are electrical insulated from each other. The third voltage is larger than the first voltage and the second voltage.

According to a second aspect of the present invention, a testing method of a semiconductor layout structure is disclosed. The testing method includes the following steps. The semiconductor layout structure is provided. The semiconductor layout structure includes a device under test (DUT). The DUT includes a plurality of metal-oxide-semiconductor (MOS) transistors. Each of the MOS transistors includes a first terminal, a second terminal and a third terminal. A first voltage is applied to a first testing pad coupled to the first terminals. A second voltage is applied to a second testing pad coupled to the second terminals. A third voltage is applied to a plurality of third testing pads respectively coupled to the third terminals. The third testing pads are electrical insulated from each other. The third voltage is larger than the first voltage and the second voltage. A current passing through the third terminal of each of the MOS transistors is measured. A breakdown time of each of the MOS transistors is obtained according to the current.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 illustrates a circuit diagram of a semiconductor layout structure according to one embodiment of the invention;

FIG. 2 illustrates a flowchart of a testing method of the semiconductor layout structure according to one embodiment of the invention;

FIG. 3 illustrates a changing curve of the current passing through a third terminal of one of the MOS transistor;

FIG. 4 illustrates a life time curve; and

FIGS. 5 and 6 illustrate two experiments for a leakage current passing through dielectric films of different MOS transistors.

### DETAILED DESCRIPTION OF THE INVENTION

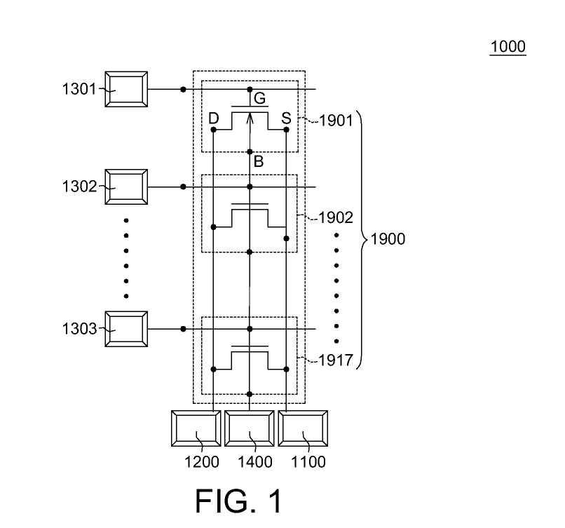

Please referring to FIG. 1, FIG. 1 illustrates a circuit diagram of a semiconductor layout structure 1000 according to one embodiment of the invention. The semiconductor layout structure 1000 includes a device under test (DUT) 1900, a first testing pad 1100, a second pad 1200, a plurality of third testing pads 1301, 1302, . . . , 1317 and a fourth testing pad 1400. The DUT 1900 is a semiconductor device, such as multiple MOSFET, memory cell, interconnect routing structure, passive device. The first testing pad 1100, the second test pad 1200, the third testing pads 1301, 1302, . . . , 1317 and the fourth testing pad 1400 are used for being applied voltages during a testing process.

The semiconductor layout structure 1000 is used for testing the time dependent dielectric breakdown (TDDB). The breakdown time of a dielectric film of the DUT 1900 can be measured under different predetermined specific conditions. Then, the life time of the dielectric film under a normal condition can be forecasted.

The DUT 1900 includes a plurality of metal-oxide-semiconductor (MOS) transistors 1901, 1902, . . . , 1917. For example, each of MOS transistors 1901, 1902, . . . , 1917 may be a P type metal-oxide-semiconductor field-effect transistor (MOSFET), a N type MOSFET or a complementary metal-oxide-semiconductor (CMOS) transistor.

Each of the MOS transistors 1901, 1902, . . . , 1917 includes a first terminal, a second terminal, a third terminal and a fourth terminal. For example, each first terminal may be a source electrode S of each of the MOS transistors 1901, 1902, . . . , 1917, each second terminal may be a drain electrode D of each of the MOS transistors 1901, 1902, . . . , 1917, each third terminal may be a gate electrode G of each of the MOS transistors 1901, 1902, . . . , 1917 and each fourth terminal may be a bulk electrode B of each of the MOS transistors 1901, 1902, . . . , 1917. In one embodiment, each fourth terminal is directly connected to a ground voltage, and each fourth terminal is not needed to be applied any voltage. Therefore, the fourth testing pad 1400 can be omitted.

In the present embodiment, all of the first terminals are coupled to one first testing pad 1100, all of the second terminals are coupled to one second testing pad 1200, and all of the fourth terminals are coupled to one fourth testing pad 1400. Each of the third terminals is coupled to one of the third testing pads 1301, 1302, . . . , 1317. The number of the first testing pad 1100, the second testing pad 1100 or the fourth testing pad 1400 is one, and the number of the third test pads 1301, 1302, . . . , 1317 is plurality. For example, the DUT 1900 of FIG. 1 includes 17 MOS transistors 1901, 1902, . . . , 1917. The number of the first testing pad 1100, the second testing pad 1200 or the fourth testing pad 1400 is one, and the number of the third test pads 1301, 1302, . . . , 1317 is 17.

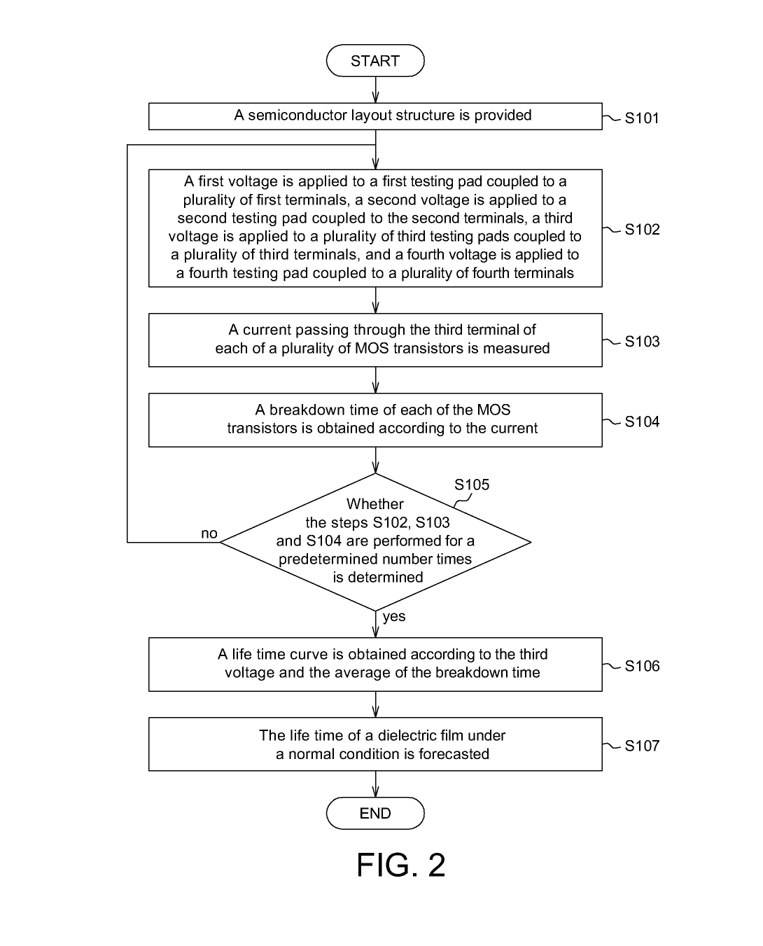

A testing method of the semiconductor layout structure 1000 is illustrated below by ways of embodiments of the invention. Please referring to FIG. 2, FIG. 2 illustrates a flowchart of the testing method of the semiconductor layout structure 1000 according to one embodiment of the invention. In step S101, the semiconductor layout structure 1000 is provided.

In step S102, a first voltage is applied to the first testing pad 1100 coupled to the first terminals, a second voltage is applied to the second testing pad 1200 coupled to the second terminals, a third voltage is applied to the third testing pads 1301, 1302, . . . , 1317 coupled to the third terminals, and a fourth voltage is applied to the fourth testing pad 1400 coupled to the fourth terminals.

In the step S102, the third testing pads 1301, 1302, . . . , 1317 are electrical insulated from each other. The third voltage can be applied to the third testing pads 1301, 1302, . . . , 1317 sequentially or at the same time. That is to say, the MOS transistor 1901, 1902, . . . , 1917 can be tested sequentially or at the same time. The third voltage is larger than the first voltage, the second voltage and the fourth voltage. For example, the first voltage, the second voltage and the fourth voltage can be 0 volt, and the third voltage can be 1.6, 1.7 or 1.8 volts.

In step S103, a current passing through the third terminal of each of the MOS transistors 1901, 1902, . . . , 1917 is measured. In the step S103, the current passing through the third terminal of each of the MOS transistors 1901, 1902, . . . , 1917 is measured between the third terminal and the fourth terminal which is a leakage current. In the present embodiment, the reliability of the dielectric film between the gate electrode and the bulk electrode can be measured by the leakage current. If the leakage current is low, then the performance of the dielectric film is good; otherwise, the performance of the dielectric film is not good.

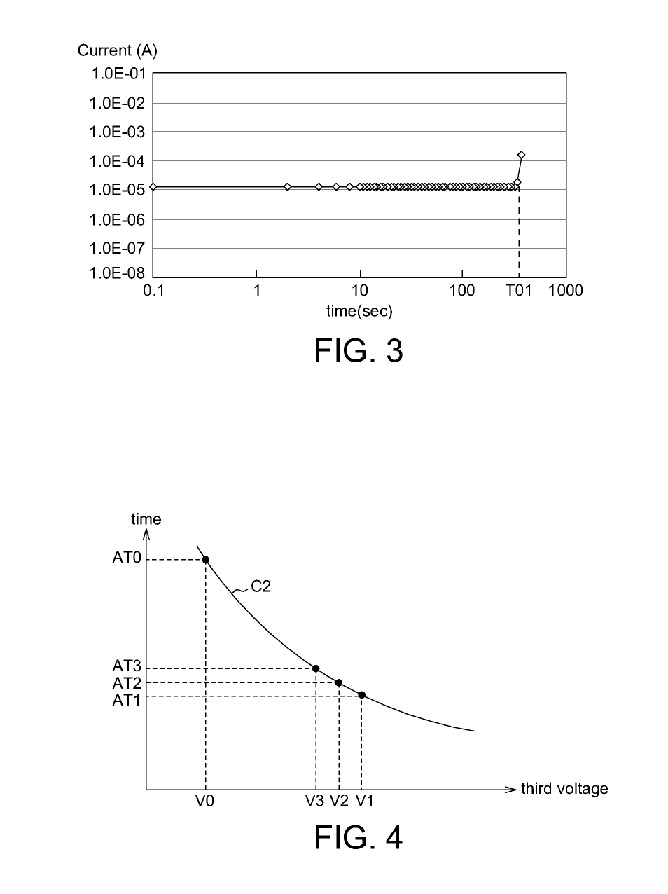

In step S104, a breakdown time of each of the MOS transistors 1901, 1902, . . . , 1917 is obtained according to the current. Please referring to FIG. 3, FIG. 3 illustrates a changing curve C1 of the current passing through the third terminal of the MOS transistor 1901. In the initial stage, the current is stable at a fix level. Then, at the time T01, the current is greatly increased due to the breakdown of the dielectric film. The time T01 is the breakdown time of the MOS transistor 1901.

For all of the MOS transistors 1901, 1902, . . . , 1917, the breakdown time of all of the MOS transistors 1901, 1902, . . . , 1917 can be obtained. The average AT1 (shown in FIG. 4) of the breakdown time of all of the MOS transistors 1901, 1902, . . . , 1917 can be calculated accordingly.

In step S105, whether the steps S102, S103 and S104 are performed for a predetermined number times is determined. If the steps S102, S103 and S104 are performed for the predetermined number times, then the process proceeds to step S106; if the steps S102, S103 and S104 are not performed for the predetermined number times, then the process returns to step S102. For example, the predetermined number of times can be three. The third voltage is changed at each time. For example, the third voltage can be three different predetermined voltages V1, V2 and V3 (shown in FIG. 4) at the three iterations and the average AT1, AT2 and AT3 (shown in FIG. 4) of the breakdown time of all of the MOS transistors 1901, 1902, . . . , 1917 are calculated.

In step S106, please referring to FIG. 4, FIG. 4 illustrates a life time curve C2. The life time curve C2 is obtained according to the third voltage and the average of the breakdown time at three iterations.

In step S107, the life time of the dielectric film under a normal condition is forecasted. In the normal condition, the third voltage applied to the dielectric film is controlled to be a particular voltage V0 which is lower than the predetermined voltages V1, V2 and V3. According to the life time curve C2, the time AT0 corresponding the particular voltage V0 can be obtained to be the lift time of the dielectric film. That is to say, even if the lift time under the normal condition is very long, the life time can be forecasted by applying low third voltages.

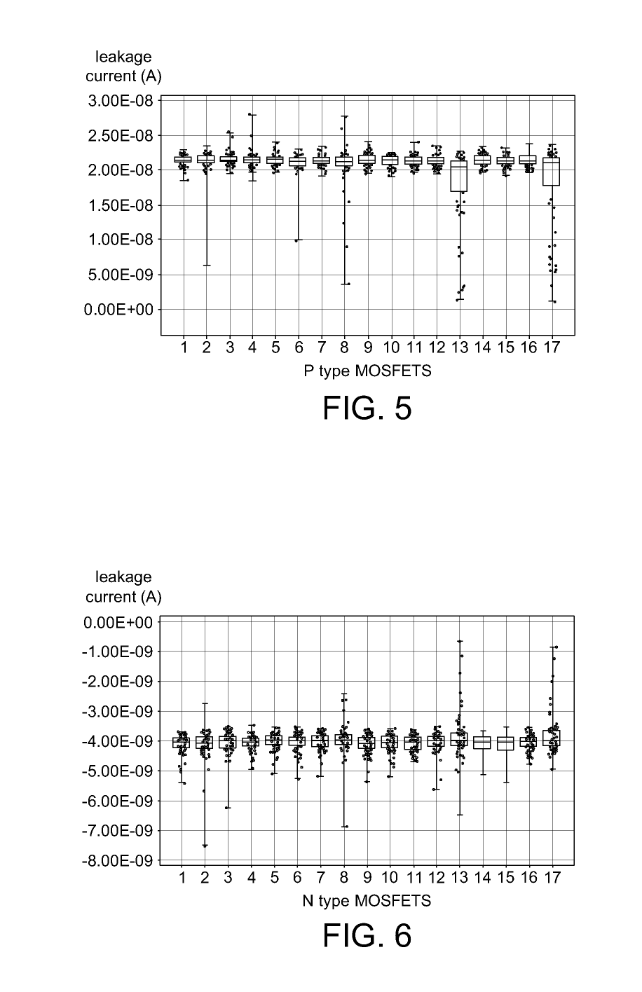

Please referring to FIGS. 5 and 6, FIGS. 5 and 6 illustrate two experiments for the leakage current passing through the dielectric films of different MOS transistors. In FIG. 5, 17 N type MOSFETS are experimented, and the difference of the leakage current among the 17 N type MOSFETS is less than 2.5E-9. In FIG. 5, 17 P type MOSFETS are experimented, and the difference of the leakage current among the 17 P type MOSFETS is less than 7E-9. The difference of the leakage current among the 17 N type MOSFETS and the difference of the leakage current among the 17 P type MOSFETS are very low. The slight variation of the leak current among the different MOS transistors proofs that the average of the breakdown time among the different MOS transistors is a useful information for representing the information of the DUT 1000.

Based on the above, the semiconductor layout structure and the testing method thereof described above in embodiments of the invention do not need any extra wafer acceptance test (WAT) tool. Further, the number of the MOS transistors can be easily increased to reduce the error bar due to the high sample size. Moreover, even if the number of the MOS transistors is large, the testing time is still less and the testing area is still small.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor layout structure, comprising:
a device under test (DUT) including a plurality of metal-oxide-semiconductor (MOS) transistors, each of the MOS transistors including a first terminal, a second terminal and a third terminal;
a first testing pad, coupled to the first terminals for being applied a first voltage;
a second testing pad, coupled to the second terminals for being applied a second voltage; and
a plurality of third testing pads, respectively coupled to the third testing pads for being applied a third voltage, wherein the third testing pads are electrical insulated from each other, and the third voltage is larger than the first voltage and the second voltage.

2. The semiconductor layout structure according to claim 1, wherein each of the first terminals is a source electrode, each of the second terminals is a drain electrode, and each of the third terminals is a gate electrode.

3. The semiconductor layout structure according to claim 1, wherein each of the MOS transistors further includes a fourth terminal, and the semiconductor layout structure further comprises a fourth pad coupled to the fourth terminals for being applied a fourth voltage.

4. The semiconductor layout structure according to claim 3, wherein each of fourth terminals is a bulk electrode.

5. The semiconductor layout structure according to claim 1, wherein each of the MOS transistors is a P type metal-oxide-semiconductor field-effect transistor (MOSFET), a N type MOSFET or a complementary metal-oxide-semiconductor (CMOS) transistor.

6. A testing method of a semiconductor layout structure, comprising:
providing the semiconductor layout structure including a device under test (DUT), wherein the DUT includes a plurality of metal-oxide-semiconductor (MOS) transistors, and each of the MOS transistors includes a first terminal, a second terminal and a third terminal;
applying a first voltage to a first testing pad coupled to the first terminals;
applying a second voltage to a second testing pad coupled to the second terminals;
applying a third voltage to a plurality of third testing pads respectively coupled to the third terminals, wherein the third testing pads are electrical insulated from each other, and the third voltage is larger than the first voltage and the second voltage;
measuring a current passing through the third terminal of each of the MOS transistors; and
obtaining a breakdown time of each of the MOS transistors according to the current.

7. The testing method of the semiconductor layout structure according to claim 6, wherein the step of applying the first voltage, the step of applying the second voltage, the step of applying the third voltage, the step of measuring the current and the step of obtaining the breakdown time are repeated for at least three times, the third voltage is changed at each time, and the testing method further comprises:
obtaining a life time curve of the DUT according to the third voltage and the breakdown time.

8. The testing method of the semiconductor layout structure according to claim 6, wherein in the step of applying the third voltage, the third voltage is applied to the third testing pads sequentially.

9. The testing method of the semiconductor layout structure according to claim 6, wherein in the step of applying the third voltage, the third voltage is applied to the third testing pads at the same time.

10. The testing method of the semiconductor layout structure according to claim 6, wherein in the step of measuring the current, the current passing through the third terminal of each of the MOS transistors is measured between the third terminal and a fourth terminal of each of the MOS transistors.

11. The testing method of the semiconductor layout structure according to claim 10, wherein each of the third terminals is a gate electrode, and each of the fourth terminals is a bulk electrode.

12. The testing method of the semiconductor layout structure according to claim 6, wherein each of the first terminals is a source electrode, each of the second terminals is a drain electrode, and each of the third terminals is a gate electrode.

13. The testing method of the semiconductor layout structure according to claim 6, wherein each of the each of the MOS transistors further includes a fourth terminal, and the testing method further comprises:
applying a fourth voltage to a fourth pad coupled to the fourth terminals.

14. The testing method for testing the DUT according to claim 13, wherein each of the fourth terminals is a bulk electrode.

15. The testing method of the semiconductor layout structure according to claim 6, wherein each of the MOS transistors is a P type metal-oxide-semiconductor field-effect transistor (MOSFET), a N type MOSFET or a complementary metal-oxide-semiconductor (CMOS) transistor.
